(19) United States
(12) Patent Application Publication
(10) Pub. No.: US 2010/0102851 A1
(43) Pub. Date: Apr. 29, 2010

(54) P-Type Source Bias Virtual Ground Restoration Apparatus

(75) Inventors: James Muha, Phoenix, AZ (US); Jinhui Chen, Chandler, AZ (US); Dwight Klaus, Phoenix, AZ (US)

Correspondence Address: King & Spalding LLP, 401 Congress Avenue, Suite 3200, Austin, TX, 78701, US

(73) Assignee: MICROCHIP TECHNOLOGY INCORPORATED, Chandler, AZ (US)

(21) Appl. No.: 12/501,578

(22) Filed: Jul. 13, 2009

Related U.S. Application Data
(60) Provisional application No. 61/108,642, filed on Oct. 27, 2008.

(51) Int. Cl. H03K 19/0175

(52) U.S. Cl. 326/81; 326/62

(57) ABSTRACT

A virtual ground restoration circuit is used to substantially eliminate excessive current from occurring in an integrated circuit device having two or more logic circuit modules in different voltage domains. Excessive current is caused when a signal between the two or more logic circuit modules in different voltage domains is at logic “0” and one of the logic circuit modules is biased at a voltage level above the true ground or common power source voltage, V_{SS}, of the integrated circuit device.

### RELATED PATENT APPLICATION

This application claims priority to commonly owned U.S. Provisional Patent Application Ser. No. 61/108,642; filed Oct. 27, 2008; entitled “P-Type Source Bias Virtual Ground Restoration Apparatus,” by James Muha, Jinhui Chen and Dwight Klaus; and is hereby incorporated by reference herein for all purposes.

### TECHNICAL FIELD

The present disclosure relates to integrated circuit devices having logic circuits capable of low power levels, and more particularly, to a ground restoration circuit (GRC) that substantially reduces excessive current paths in the logic circuits caused when a logic “0” signal is asserted that is not at substantially true ground or power source common of the logic circuits, and is used to provide a logic “0” to a circuit that operates on substantially true ground.

### BACKGROUND

An integrated circuit device may electrically alter the threshold voltage of its NMOS transistors by raising the Vss power rail voltage above the bulk (e.g., well, tub, or substrate) voltage of the integrated circuit substrate (sometimes referred to as a “virtual ground”). This technique is commonly used to reduce the power consumption of the integrated circuit device due to sub-threshold leakage. Generally, the integrated circuit device will have two or more independent voltage domains to service respective core logic circuits that have signal paths therebetween; some of these voltage domains may operate on the virtual ground, and other voltage domains may operate on true ground.

A problem exists in an integrated circuit device when a virtual ground of a signal source at a logic “0” is higher, e.g., more positive, than V_{SS}, in that a logic gate may consume excessive current and/or state corruption when a logic “0” signal to that logic gate does not have the ground level thereof restored to true ground.

### SUMMARY

Therefore, a need exists for an apparatus that will substantially prevent excessive current from occurring in the logic circuits of an integrated circuit device when a logic “0” signal is biased at a voltage level above the true ground or power source common voltage, V_{SS}, of these logic circuits.

According to a specific example embodiment of this disclosure, an integrated circuit device having ground restoration circuits for restoring a logic “0” signal at a virtual ground to substantially a power source ground of the integrated circuit device comprises: a plurality of core logic circuits operating in independent voltage domains are fabricated on an integrated circuit die, wherein at least one of the independent voltage domains operates at a virtual ground and another at least one of the independent voltage domains operates at a power source ground, wherein the virtual ground is at a more positive voltage then the power source ground; a plurality of ground restoration circuits, each of the plurality of ground restoration circuits is coupled between a one of the plurality of core logic circuits operating in the virtual ground voltage domain and a one of the plurality of core logic circuit operating in the power source ground voltage domain, wherein each of the plurality of ground restoration circuits comprises: a first P-channel metal oxide semiconductor (PMOS) transistor (202) having a gate, source and drain; a second PMOS transistor (204) having a gate, source and drain; a first N-channel metal oxide semiconductor (NMOS) transistor (208) having a gate, source and drain; a second NMOS transistor (206) having a gate, source and drain; a first inverter (210) having an input and an output; a second inverter (212) having an input and an output; the sources of the first PMOS transistor (202) and the second PMOS transistor (204), the first inverter (210) and second inverter (212) are coupled to a power source voltage; the sources of the first NMOS transistor (208) and the second NMOS transistor (206), and the second inverter are coupled to the power source ground; the first inverter (210) is coupled to the virtual ground; the gate of the first PMOS transistor (202) and the input of the first inverter (210) are coupled to a signal from a core logic circuit operating in the virtual ground voltage domain; the drains of the first PMOS transistor (202) and first NMOS transistor (208), the gate of the second NMOS transistor (206), and the input of the second inverter (212) are coupled together; the drains of the second PMOS transistor (204) and second NMOS transistor (206), and the gate of the first NMOS transistor (208) are coupled together; the output of the first inverter (210) is coupled to the gate of the second PMOS transistor (204); whereby when the signal from the core logic circuit operating in the virtual ground voltage domain is a logic “0” at a voltage greater than the power source ground the logic “0” signal is shifted to substantially the power source ground from the output of the second inverter.

According to another specific example embodiment of this disclosure, an apparatus for restoring a logic “0” signal at a virtual ground to substantially a power source ground comprises: a first P-channel metal oxide semiconductor (PMOS) transistor (202) having a gate, source and drain; a second PMOS transistor (204) having a gate, source and drain; a first N-channel metal oxide semiconductor (NMOS) transistor (208) having a gate, source and drain; a second NMOS transistor (206) having a gate, source and drain; a first inverter (210) having an input and an output; a second inverter (212) having an input and an output; the sources of the first PMOS transistor (202) and the second PMOS transistor (204), the first inverter (210) and second inverter (212) are coupled to a power source voltage; the sources of the first NMOS transistor (208) and the second NMOS transistor (206), and the second inverter are coupled to a power source ground; the first inverter (210) is coupled to a virtual ground; the gate of the first PMOS transistor (202) and the input of the first inverter (210) are coupled to a signal from a logic circuit operating in a virtual ground voltage domain; the drains of the first PMOS transistor (202) and first NMOS transistor (208), the gate of the second NMOS transistor (206), and the input of the second inverter (212) are coupled together; the drains of the second PMOS transistor (204) and second NMOS transistor (206), and the gate of the first NMOS transistor (208) are coupled together; the output of the first inverter (210) is coupled to the gate of the second PMOS transistor (204); whereby when the signal from the logic circuit operating in the virtual ground voltage domain is a logic “0” at a voltage greater than the power source ground the logic “0” signal is shifted to substantially the power source ground from the output of the second inverter.

### BRIEF DESCRIPTION OF THE DRAWINGS

A more complete understanding of the present disclosure may be acquired by referring to the following description taken in conjunction with the accompanying drawings wherein:

FIG. 1 is a schematic block diagram of an integrated circuit device comprising a virtual ground restoration circuit coupled between two logic circuit modules having independent voltage domains, all fabricated on the integrated circuit device, according to the teachings of this disclosure;

FIG. 2 is a schematic diagram of a virtual ground restoration circuit that prevents excessive current from being drawn when a signal at a logic “0” is biased at a voltage level above a true ground or power source common voltage of an integrated circuit device, according to a specific example embodiment of this disclosure; and

FIG. 3 is a schematic diagram of a portion of the virtual ground restoration circuit shown in FIG. 2.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawing, the details of specific example embodiments are schematically illustrated. Like elements in the drawings will be represented by like numbers, and similar elements will be represented by like numbers with a different lower case letter suffix.

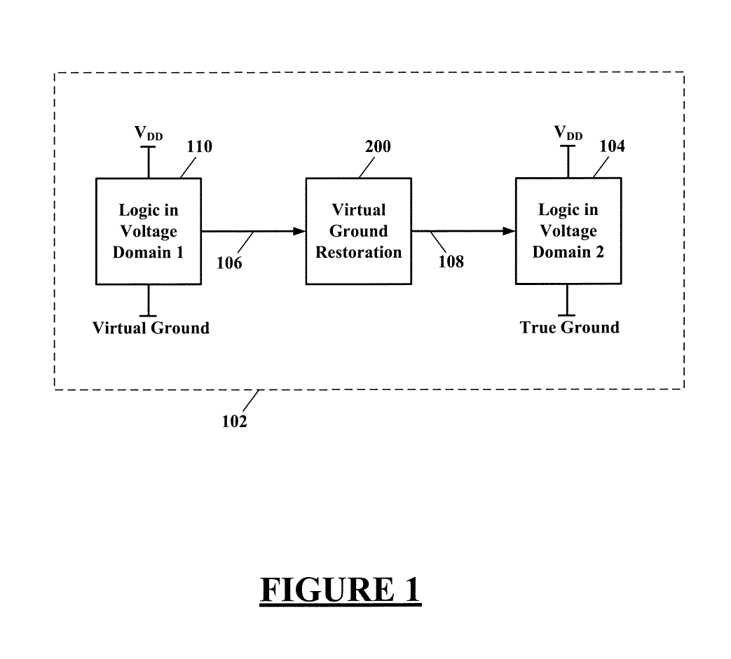

Referring to FIG. 1, depicted is a schematic block diagram of an integrated circuit device comprising a virtual ground restoration circuit coupled between two logic circuit modules having independent voltage domains, all fabricated on the integrated circuit device, according to the teachings of this disclosure. An integrated circuit device 102 comprises first core logic circuits 110, a virtual ground restoration circuit 200 and second core logic circuits 104. The first core logic circuits 110 are in a first voltage domain, and the second core logic circuits 104 are in a second voltage domain. The first and second voltage domains may not have substantially the same common or ground voltage potential, e.g., the first voltage domain is at a virtual ground potential while the second voltage domain is at a true ground potential. The virtual and true ground potentials may be different enough wherein if a logic “0” signal is directly coupled between the first and second core logic circuits 110 and 104, excessive current will occur in one or both of the first and second core logic circuits 110 and 104.

According to the teaching of this disclosure, when a signal is at a logic “0” level that is biased above the true ground or power source common voltage, V_{SS}, of the second core logic circuits 104, the virtual ground restoration circuit 200 will shift the logic “0” signal to a non-biased logic “0” level at substantially V_{SS}. A plurality of virtual ground restoration circuits 200 may be implemented in the integrated circuit device, one for each of a plurality of second core logic circuits 104 operating at the true ground or power source common voltage, V_{SS}, as shown in FIGS. 1-3.

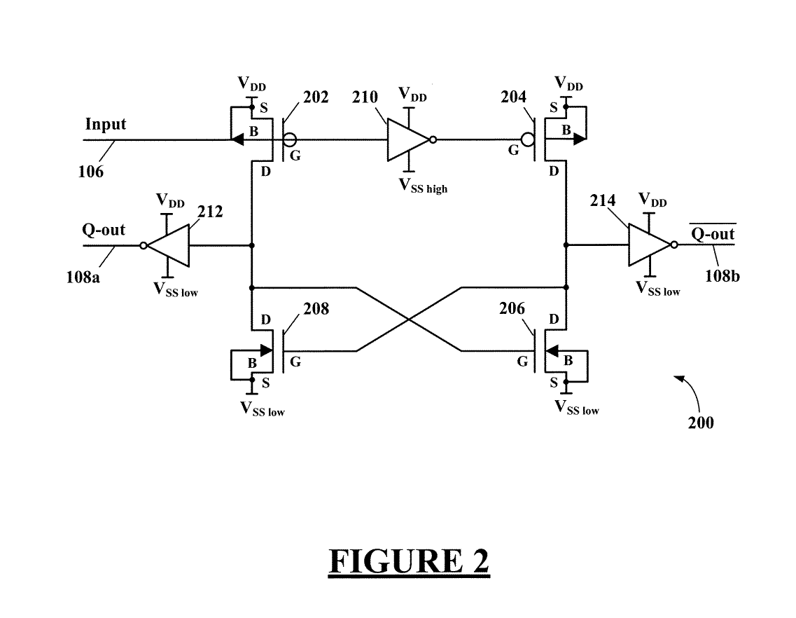

Referring to FIG. 2, depicted is a schematic diagram of a virtual ground restoration circuit that prevents excessive current from being drawn when a signal at a logic “0” is biased at a voltage level above a true ground or power source common voltage of an integrated circuit device, according to a specific example embodiment of this disclosure. A virtual ground is always at a higher, e.g., more positive, voltage than is true ground or power source common voltage (V_{SS}). Logic level signals on input 106 may be at substantially the power source voltage, V_{DD}, for a logic “1” or at substantially virtual ground for a logic “0.” The signal voltage level at the input 106 is dependent upon the operational modes of the integrated circuit device 102 as more fully described hereinbelow.

In a normal operation mode, the virtual ground of the signal source, e.g., first core logic circuits 110, that is coupled to the signal line 106 may be substantially the same as V_{SS}. In a standby mode having a back bias input, the virtual ground of the signal source coupled to the signal line 106 may be higher, e.g., more positive, than V_{SS} when the signal from the signal source is at a logic “0.”

Transistors 202 and 204 are P-channel metal oxide semiconductor (PMOS) transistors arranged in a differential input configuration. Inverter 210 is used in providing differential signals to the inputs for the PMOS transistors 202 and 204. The inverter 210 is coupled to V_{DD} and to a voltage at approximately the virtual ground. The inverters 212 and 214 provide load isolation to the output nodes 108a and 108b. PMOS transistors 202 and 204 in combination with N-channel metal oxide semiconductor (NMOS) transistors 206 and 208 create a cross-coupled latch that holds the signal levels stable on the output nodes 108a and 108b. Connections of each source, S; drain, D; gate, G; and bulk (e.g., well, tub, or substrate), B; of the transistors 202-208 are as shown in FIG. 2.

If the PMOS transistors 202 and 204 are sized larger than the NMOS transistors 206 and 208, then a logic “0” signal at the virtual ground reference will still turn on the PMOS portion of the level shifter 200 so as to convert the logic “0” input signal to substantially V_{SS}. There is substantially no leakage path between V_{DD} and V_{SS}.

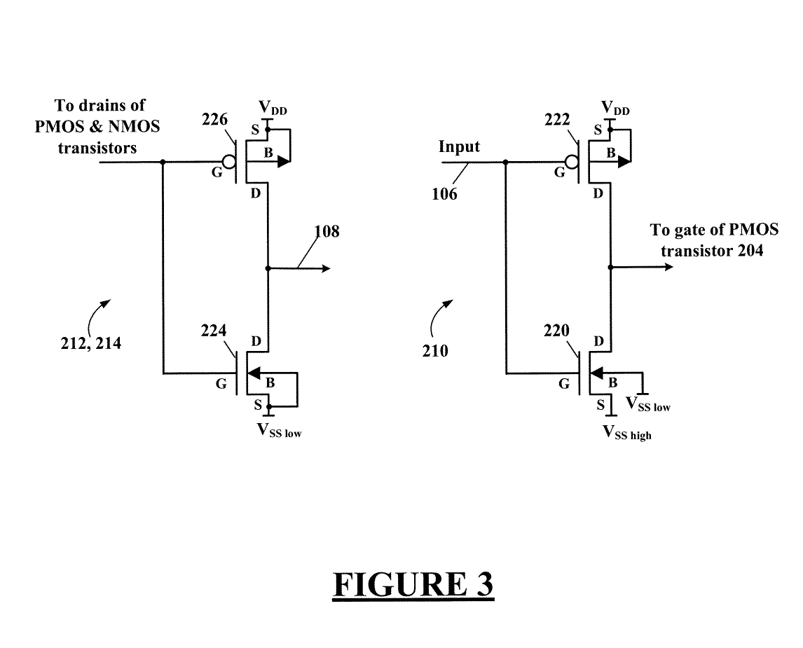

Referring to FIG. 3, depicted is a schematic diagram of a portion of the virtual ground restoration circuit shown in FIG. 2. The inverter 210 may comprise totem pole connected PMOS transistor 222 and NMOS transistor 220 coupled to the input 106 and the gate of the PMOS transistor 204. Connections of each source, S; drain, D; gate, G; and bulk (e.g., well, tub, or substrate), B; of the transistors 220 and 222 are as shown in FIG. 3. The inverters 212 and 214 may each comprise totem pole connected PMOS transistor 226 and NMOS transistor 224 coupled to the drains of the respective PMOS and NMOS transistors and having an output 108. Connections of each source, S; drain, D; gate, G; and (e.g., well, tub, or substrate), B; of the transistors 224 and 226 are as shown in FIG. 3.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. An integrated circuit device having ground restoration circuits for restoring a logic “0” signal at a virtual ground to substantially a power source ground of the integrated circuit device, comprising:
a plurality of core logic circuits operating in independent voltage domains are fabricated on an integrated circuit die, wherein at least one of the independent voltage domains operates at a virtual ground and another at least one of the independent voltage domains operates at a power source ground, wherein the virtual ground is at a more positive voltage then the power source ground;
a plurality of ground restoration circuits, each of the plurality of ground restoration circuits is coupled between a one of the plurality of core logic circuits operating in the virtual ground voltage domain and a one of the plurality of core logic circuit operating in the power source ground voltage domain, wherein each of the plurality of ground restoration circuits comprises:
a first P-channel metal oxide semiconductor (PMOS) transistor (202) having a gate, source, drain and bulk;
a second PMOS transistor (204) having a gate, source and drain;
a first N-channel metal oxide semiconductor (NMOS) transistor (208) having a gate, source, drain and bulk;
a second NMOS transistor (206) having a gate, source, drain and bulk;
a first inverter (210) having an input and an output;
a second inverter (212) having an input and an output;
the sources and bulk of the first PMOS transistor (202) and the second PMOS transistor (204), the first inverter (210) and second inverter(212) are coupled to a power source voltage;
the sources and bulk of the first NMOS transistor (208) and the second NMOS transistor (206), and the second inverter are coupled to the power source ground;
the first inverter (210) is coupled to the virtual ground;
the gate of the first PMOS transistor (202) and the input of the first inverter (210) are coupled to a signal from a core logic circuit operating in the virtual ground voltage domain;
the drains of the first PMOS transistor (202) and first NMOS transistor (208), the gate of the second NMOS transistor (206), and the input of the second inverter (212) are coupled together;
the drains of the second PMOS transistor (204) and second NMOS transistor (206), and the gate of the first NMOS transistor (208) are coupled together;
the output of the first inverter (210) is coupled to the gate of the second PMOS transistor (204);
whereby when the signal from the core logic circuit operating in the virtual ground voltage domain is a logic “0” at a voltage greater than the power source ground the logic “0” signal is shifted to substantially the power source ground from the output of the second inverter.

2. The integrated circuit device according to claim 1, wherein the first NMOS transistor (208) and the second NMOS transistor (206) are configured as a cross-coupled latch.

3. The integrated circuit device according to claim 1, wherein the first inverter (210) comprises:
a third PMOS transistor (222) having a gate, source, drain and bulk; and
a third NMOS transistor (220) having a gate, source, drain and bulk;
the gates of the third PMOS transistor (222) and the third NMOS transistor (220) are coupled to the signal from a core logic circuit operating in the virtual ground voltage domain;
the source and bulk of the third PMOS transistor (222) are coupled to the power source voltage;
the source of the third NMOS transistor (220) is coupled to the virtual ground;
the bulk of the third NMOS transistor (220) is coupled to the power source ground; and
the drains of the third PMOS transistor (222) and the third NMOS transistor (220) are coupled to the gate of the second PMOS transistor (204).

4. The integrated circuit device according to claim 1, wherein the second inverter (212) comprises:
a fourth PMOS transistor (226) having a gate, source, drain and bulk; and
a fourth NMOS transistor (224) having a gate, source, drain and bulk;
the gates of the fourth PMOS transistor (226) and the fourth NMOS transistor (224) are coupled to the drains of the first PMOS transistor (202) and the first NMOS transistor (208);
the source and bulk of the fourth PMOS transistor (226) are coupled to the power source voltage;
the source and bulk of the fourth NMOS transistor (224) are coupled to the power source ground; and
the drains of the fourth PMOS transistor (226) and the fourth NMOS transistor (224) are coupled as the output of the second inverter (212).

5. The integrated circuit device according to claim 1, further comprising a third inverter (214) having an input coupled to the drains of the second PMOS transistor (204) and the second NMOS transistor (206), and an output generating a signal that is inverted from the second inverter (212).

6. The integrated circuit device according to claim 5, wherein the third inverter (214) comprises:
a fifth PMOS transistor (226a) having a gate, source, drain and bulk; and
a fifth NMOS transistor (224a) having a gate, source, drain and bulk;
the gates of the fifth PMOS transistor (226a) and the fifth NMOS transistor (224a) are coupled to the drains of the second PMOS transistor (204) and the second NMOS transistor (206);
the source and bulk of the fifth PMOS transistor (226a) are coupled to the power source voltage;
the source and bulk of the fifth NMOS transistor (224a) are coupled to the power source ground; and
the drains of the fifth PMOS transistor (226a) and the fifth NMOS transistor (224a) are coupled as the output of the third inverter (214).

7. The integrated circuit device according to claim 1, wherein the bulk is a well of the integrated circuit device.

8. The integrated circuit device according to claim 1, wherein the bulk is a tub of the integrated circuit device.

9. The integrated circuit device according to claim 1, wherein the bulk is a substrate of the integrated circuit device.

10. An apparatus for restoring a logic “0” signal at a virtual ground to substantially a power source ground, comprising:
a first P-channel metal oxide semiconductor (PMOS) transistor (202) having a gate, source, drain and bulk;
a second PMOS transistor (204) having a gate, source, drain and bulk;
a first N-channel metal oxide semiconductor (NMOS) transistor (208) having a gate, source, drain and bulk;
a second NMOS transistor (206) having a gate, source, drain and bulk;
a first inverter (210) having an input and an output;
a second inverter (212) having an input and an output;
the sources and bulk of the first PMOS transistor (202) and the second PMOS transistor (204), the first inverter (210) and second inverter (212) are coupled to a power source voltage;
the sources and bulk of the first NMOS transistor (208) and the second NMOS transistor (206), and the second inverter are coupled to a power source ground;
the first inverter (210) is coupled to a virtual ground;
the gate of the first PMOS transistor (202) and the input of the first inverter (210) are coupled to a signal from a logic circuit operating in a virtual ground voltage domain;
the drains of the first PMOS transistor (202) and first NMOS transistor (208), the gate of the second NMOS transistor (206), and the input of the second inverter (212) are coupled together;
the drains of the second PMOS transistor (204) and second NMOS transistor (206), and the gate of the first NMOS transistor (208) are coupled together;
the output of the first inverter (210) is coupled to the gate of the second PMOS transistor (204);
whereby when the signal from the logic circuit operating in the virtual ground voltage domain is a logic “0” at a voltage greater than the power source ground the logic “0” signal is shifted to substantially the power source ground from the output of the second inverter.

11. The apparatus according to claim 10, wherein the first NMOS transistor (208) and the second NMOS transistor (206) are configured as a cross-coupled latch.

12. The apparatus according to claim 10, wherein the first inverter (210) comprises:
a third PMOS transistor (222) having a gate, source and bulk; and
a third NMOS transistor (220) having a gate, source and bulk;
the gates of the third PMOS transistor (222) and the third NMOS transistor (220) are coupled to the signal from a core logic circuit operating in the virtual ground voltage domain;
the source and bulk of the third PMOS transistor (222) are coupled to the power source voltage;
the source of the third NMOS transistor (220) is coupled to the virtual ground;
the bulk of the third NMOS transistor (220) is coupled to the power source ground; and
the drains of the third PMOS transistor (222) and the third NMOS transistor (220) are coupled to the gate of the second PMOS transistor (204).

13. The apparatus according to claim 10, wherein the second inverter (212) comprises:
a fourth PMOS transistor (226) having a gate, source, drain and bulk; and
a fourth NMOS transistor (224) having a gate, source, drain and bulk;
the gates of the fourth PMOS transistor (226) and the fourth NMOS transistor (224) are coupled to the drains of the first PMOS transistor (202) and the first NMOS transistor (208);
the source and bulk of the fourth PMOS transistor (226) are coupled to the power source voltage;
the source and bulk of the fourth NMOS transistor (224) are coupled to the power source ground; and
the drains of the fourth PMOS transistor (226) and the fourth NMOS transistor (224) are coupled as the output of the second inverter (212).

14. The apparatus according to claim 10, further comprising a third inverter (214) having an input coupled to the drains of the second PMOS transistor (204) and the second NMOS transistor (206), and an output generating a signal that is inverted from the second inverter (212).

15. The apparatus according to claim 14, wherein the third inverter (214) comprises:
a fifth PMOS transistor (226a) having a gate, source, drain and bulk; and
a fifth NMOS transistor (224a) having a gate, source, drain and bulk;
the gates of the fifth PMOS transistor (226a) and the fifth NMOS transistor (224a) are coupled to the drains of the second PMOS transistor (204) and the second NMOS transistor (206);
the source and bulk of the fifth PMOS transistor (226a) are coupled to the power source voltage;
the source and bulk of the fifth NMOS transistor (224a) are coupled to the power source ground; and
the drains of the fifth PMOS transistor (226a) and the fifth NMOS transistor (224a) are coupled as the output of the third inverter (214).

16. The apparatus according to claim 10, wherein the bulk is a well of the integrated circuit device.

17. The apparatus according to claim 10, wherein the bulk is a tub of the integrated circuit device.

18. The apparatus according to claim 10, wherein the bulk is a substrate of the integrated circuit device.
